(19) United States
(12) Patent Application Publication
(10) Pub. No.: US 2004/0216838 A1
(43) Pub. Date: Nov. 4, 2004

(54) Processes for the production of components fo electronic apparatuses

(76) Inventors: Anders V. Ekman, Kallered (SE); Richard Stossel, Muttenz (CH); Thierry Becret, Blotzheim (FR); Thierry Tschan, Rosenau (FR); Kurt Stutz, Munchenstein (CH)

Correspondence Address: PROSKAUER ROSE LLP, PATENT DEPARTMENT, 1585 BROADWAY, NEW YORK, NY, 10036-8299, US

(21) Appl. No.: 10/478,546

(22) PCT Filed: May 15, 2002
(86) PCT No.: PCT/EP02/05348

(30) Foreign Application Priority Data
May 21, 2001 (CH) 944/01

(51) Int. Cl. H05K 3/36; H05K 3/46

(52) U.S. Cl. 156/307.3; 156/307.7; 29/830

(57) ABSTRACT

Method for the production of components for electronic apparatuses from a sheet-like substrate material, which has through-holes and indentations on at least one surface, an intermediate layer on at least one surface of the substrate material, and a metal foil adhering to said layer, comprising the steps (a) coating of a sheet-like substrate with a composition forming the intermediate layer, (b) application of the metal foil to the coating and (c) bonding of the parts by pressure and heating. The method is characterized by the use of a liquid, solvent-containing and heat-curable two-component system comprising at least one curing agent and at least one curable compound, which system is applied as the layer to at least one surface of a substrate material and then dried. A metal foil is then laminated with the resulting solid and dry layer under pressure and at elevated temperature and the layer is cured. Particularly preferably, circuit boards are produced by the method according to the invention.

The invention relates to processes for the production of components for electronic apparatuses, comprising a sheet-like substrate material which has indentations and through-holes, a metal foil and an intermediate layer located between the sheet-like substrate material and the metal foil.

Various methods for the production of components for electronic apparatuses, such as, for example, circuit boards, have already been described in the literature.

In the RCF (Resin Coated Copper Foil) process, a copper foil is coated with a partly cured and hence solid resin (EP-A 0 935 407). In the case of partly crosslinked resins, the reactivity is only limited by the solid state. Owing to the associated instability, they therefore have only a limited shelf-life. Compression of the coated copper foil with the structure layers already present and subsequent structuring result in a successive build-up of the conductor track planes. It is true that the flow properties of the partly crosslinked resin under pressure are sufficient for filling the spaces between the conductor tracks of the structured inner layer during this compression process. Metallized holes and microholes are, on the other hand, not sufficiently filled. However, completely closed holes and microholes are absolutely essential for ensuring the high reliability requirements of high-quality circuit boards. The closing of holes before the compression process is therefore ensured by additional time-consuming and expensive process steps. Furthermore, various resin layer thicknesses between the conductor tracks are required for flexible circuit board production. In the RCF process, the stocking of RCF foils having different resin layer thicknesses with a limited storage time is therefore necessary for this purpose, which is a decisive economic disadvantage.

Roll lamination with resin-coated copper foils (APL-D process) is a special application of the RCF process and has the same advantages and disadvantages as the RCF process. The roll lamination process has the advantage of a continuous process sequence whereas the RCF process is a labour-intensive and hence expensive batch process (APL-D, Ein einfacher Weg zu SBU-Schaltungen [A simple route to SBU circuits], Galvanotechnik 89 (1998) No. 7, page 2407, and APL-D, ein neues Verfahren zur Herstellung von Microvia-Leiterplatten [A novel process for the production of Microvia circuit boards], J. Willuweit, Isola AG, Düren.

In the hotmelt process (EP-B 0 698 233), the solid resin which has been liquefied at elevated temperature and is reactive is applied continuously by roll application to the inner layer structured with copper conductor tracks. The copper plating can be realized by subsequent roll lamination with copper foil or by wet chemical steps. Limited storage time and limited stability during the processing time in the melt greatly restrict the application. The closing of drilled holes and the compensation of spaces between conductor tracks and good planarity are possible in principle. However, the filling of cavity depends to a great extent on the viscosity and hence on the processing temperature. Elevated temperature leads to lower viscosity of the melt and hence to better flow behaviour, but also to a greatly restricted processing time due to the increased reactivity.

In the dry film process, a still uncrosslinked, substantially solvent-free, curable resin mixture on a nonmetallic substrate film subsequently to be removed is laminated with structured conductor track layers (Praxiserfahrungen bei der Microvia-Technologie [Practical experience with the Microvia technology], Dr. Hayao Nakahara, PLUS, page 324, paragraph 1). For bonding to the copper of the next conductor track layer, it is necessary to subject the cured surface to a roughening process before the electrochemical copper-plating process. Sufficient copper adhesion is influenced by all preceding processing procedures and variations and can be controlled only by complicated methods.

In Materials for Sequential Build Up (SBU) of HDI-Microvia Organic Substrates, Ceferino, G. Gonzales, The Board Authority March 2000 and in Application Technologies for Coating Liquid Microvia Dielectrics, Torsten Reckert, Proceeding of Technical Conference IPC Printed Circuit Expo 2000, liquid, thermally reactive resins which have been dissolved in solvents but not yet crosslinked under the processing conditions and which are applied to the inner layer are described. The solvent-containing layer is dried and cured. The cured layer must (as in the case of the cured dry film) be roughened in order to achieve sufficient copper adhesion. The wet chemical roughening and copper-plating processes are complicated and difficult to control. The planarity achievable is insufficient and necessitates expensive grinding processes before the roughening and copper-plating process.

U.S. Pat. No. 6,016,598 describes the use of flowable adhesives for bonding a core substrate, provided on the surface with conductor tracks, to the plastics side of a plastics substrate coated with copper foils, with filling of cavities between the conductor tracks during the compression and curing of the adhesive layer. The adhesive may be optionally fully preacted epoxy resin, which can be applied as a solution, the solvent removed prior to lamination. However, the use of a reactive two-component systems for producing the adhesive layer is not mentioned.

EP-A-0 275 686 describes a layer-by-layer structure for the production of circuit boards, in which copper foils with epoxy resins are laminated with a substrate having conductor tracks. The contacting of the conductor tracks is carried out by subsequent drilling so that the problem of filling of holes does not occur in this production method.

The use of liquid, solvent-containing and heat-curable compositions in the form of reactive systems of two components for producing an insulating and adhesion-promoting layer for metal foils in the production of, for example, printed circuits has been avoided to date owing to the short shelf-life thereof. It has now surprisingly been found that such compositions can be used if they are formulated just before use and apply to a substrate material and the solvent is virtually completely removed so that a solid and dry layer forms. The dry layer is thus surprisingly flowable so that, after application of a metal foil and subsequent curing under pressure, indentations and holes are surprisingly completely filled and in addition extremely high planarity is achieved, so that subsequent processing is unnecessary. The dried layer remains curable in spite of heating, and metal foils laminated under pressure and heat form a composite having surprisingly high adhesive strengths of metal foil and substrate material. The laminates obtained meet the high requirements set. Furthermore, the process is very economical and can even be automated, so that overall the disadvantages described can be avoided.

The invention relates to a method for the production of components for electronic apparatuses from a sheet-like substrate material which has through-holes and indentations on at least one surface, an intermediate layer on at least one surface of the substrate material, and a metal foil adhering to said layer, comprising steps (a) coating of a sheet-like substrate material with a composition forming the intermediate layer, (b) application of the metal foil to the coating and (c) bonding of the parts under pressure and heat, characterized in that

(d) first a liquid, solvent-containing and heat-curable two-component system is formulated from at least one curing agent and at least one curable compound,

(e) the formulation is applied as a layer to at least one surface of the substrate material,

(f) the applied layer is heated, the solvent is removed and a solid and dry layer forms, and

(g) thereafter a metal foil is applied to the dried layer and the substrate material, the layer and the metal foil are firmly bonded to one another by means of elevated temperature and elevated pressure with curing of the layer.

The expression component is understood as meaning components which are used in electronics, such as, for example, circuit boards or optoelectronic components.

The expression sheet-like substrate material is understood as meaning a structure sheet-like substance which acts as a substrate. This may be flexible or rigid. Examples of this are film or inner layers. Structured inner layers are often used. The structured inner layer may contain, for example, an insulating layer which is applied to the conductor track, it also being possible for the insulating layer to consist of a cured resin reinforced with glass fibres. In another preferred embodiment, electronic components, such as, for example, resistors, diodes for transistors, can be arranged in or on the surface of the inner layer. In another particular embodiment, optical elements, such as, for example, photodiodes, photoelectric elements, phototransistors or photoresistors, to be arranged in or on the surface of the inner layer.

The components of the formulation are stored at room temperature and are extremely stable for a relatively long time. The formulation is prepared immediately before the application by mixing the individual components and is applied immediately thereafter by means of known methods and apparatuses, such as screen printing, roller coating, curtain coating or spraying onto the sheet-like substrate material. The optimum method can be determined by a person skilled in the art in each case by appropriate preliminary experiments. The screen printing and roller coating methods are particularly suitable for the application of the coating formulation since, by the use of pressure during application of the coating formulation, cavities can be reliably and completely filled. By appropriate adaptation of the coating parameters, such as, for example, the viscosity by addition of solvent, a person skilled in the art can readily vary the layer thickness. Air inclusions which have easily led to difficulty can be readily eliminated by venting since the formulation can be adjusted to a low viscosity using solvents. The formulation can have, for example, a viscosity of less than 20 Pa·s, preferably from 3 to 20 Pa·s and particularly preferably from 5 to 15 Pa·s, measured at 25° C. according to Brookfield.

After the coating of the sheet-like substrate material of the formulation, the applied layer is dried. Typical conditions for drying are known to a person skilled in the art. The drying process is adapted so that the solvent is removed from the formulation but crosslinking of the curable resin is substantially avoided. By repeated coating, any desired intermediate layer thickness can be established.

The drying is a substantial step of the method according to the invention. The drying must be so complete that no bubble formation occurs during the subsequent compression with heating. During the drying, premature curing of the layer must be avoided. For this purpose, the temperature and the duration of the drying is tailored to the reactivity of the two-component system. The suitable temperature can readily be determined by a person skilled in the art in preliminary experiments. The temperature during the drying is in general no higher than 100° C. and may be from 40 to 100° C., preferably from 50 to 80° C. The duration of the drying substantially depends on the volatility of the solvent and on the layer thickness and may range from 10 to 120, preferably from 20 to 100, particularly preferably from 30 to 80 minutes. After the drying, a nontacky and solid layer is present. The flow of the dried layer is of exceptional importance for the quality of the components for electronic apparatuses since the desired planarity and complete filling of the cavity are achieved thereby. The consistency of the low molecular weight components in the layer ensure outstanding flow during compression and curing so that the desired properties are obtained without problems.

For process engineering reasons, parts of the sheet-like substrate material must not be coated in the outer region since these must remain uncoated for the application of the transport clamps. During the compression process, the intermediate layer is even extended to these parts so that, in the final stage, the entire surface is coated with the intermediate layer up to the edge of the surface. During the drying, the layer thickness decreases. By means of preliminary experiments, this decrease can be compensated by a person skilled in the art by greater layer thicknesses or higher concentration of the components in the solution.

The speed of the subsequent curing process is controlled by a person skilled in the art, inter alia by the method of curing, the amount of curing agent, the residence time, the temperature and the pressure. A person skilled in the art appropriately establishes the abovementioned parameters for the compression process by means of preliminary experiments. The curing can be measured indirectly by the metal adhesion (Cu adhesion measurement according to IPC-TM-650 2.4.8).

On compression of the dried intermediate layer on the sheet-like substrate material with copper foils at elevated temperature, the components form. Preferably, the metal foil is applied to the intermediate layer immediately after drying and is compressed. The surface quality of the press plate is very important for the quality of the components and hence no dirt particles and foreign particles are permitted to be present between press plates, the intermediate layer and the metal foils. Typical press conditions are, for example, from 20 to 120, preferably from 20 to 80 and particularly preferably from 20 to 60 minutes at temperatures of from 120 to 200° C. and preferably from 140 to 200° C., for example for an epoxy resin or other resins. The compression can also be carried out stepwise at increasing temperatures for different durations, it being possible to start with temperatures below 100° C., for example 80° C. More typical press conditions for other resins are known to a person skilled in the art. On compression, the slight differences in layer thickness which result from the coating and are still present after the drying are compensated. Presses which may be used are multilayer presses or continuously operating presses. In a compression process with the use of multilayer presses, from 10 to 20 components for electrical apparatuses can be simultaneously produced.

By means of the method according to the invention, the maximum curvature and distortion can be reduced to a minimum. The component producted according to the invention is planar within a tolerance of 5 μm, the planarity being determined according to IPC-TM-650 2.4.8. Subsequent grinding in order to achieve planarity is no longer necessary. A disadvantage process, i.e. a process in which material is removed again, can thus be eliminated, which is advantageous both ecologically and economically.

The coating formulation which is liquid at room temperature contains at least one heat-curable resin, at least one curing agent, optionally a curing accelerator and one or more solvents. A preferably used coating formulation is a dielectric. The coating formulation may additionally contain accelerators, fillers or additives. The molecular weights of the components are preferably in a range from 250 to 8 000, more preferably from 250 to 5 000 and particularly preferably from 250 to 2 000 Dalton.

In the cured state, the resin formed is an irreversible, three-dimensional, polymeric structure. By means of the method according to the invention, a plurality of heat-curable resins can be used. Resins which have a high glass transition temperature (Tg point) are particularly preferred. Resins whose Tg points are greater than or equal to those of FR4 resins (glass fibre-reinforced epoxy resins) are particularly preferred. These resins are very hard and dimensionally stable. In conventional processes, such resins are accordingly more difficult to process. By omitting the roughening process before the copper-plating in the application of the method according to the invention, it is possible to use resins which can be roughened only with difficult using conventional chemical swelling and etching methods.

The curable resin used is preferably selected from the group consisting of the epoxy resins, epoxyacrylate resins, acrylate resins, polyurethane resins, cyanate ester resins, benzoxazine resins, polyphenylene resins, polyimide resins and mixtures thereof. Epoxy resins are particularly preferred. Their chemical stability and the excellent adhesion properties make them particularly suitable. Aromatic epoxy resins are particularly preferred. Examples of epoxide compounds having on average more than one epoxide group in the molecule are:

I) Polyglycidyl and poly(β-methylglycidyl)esters, obtainable by reacting a compound having at least two carboxyl groups in the molecule and epichlorohydrin or β-methylepichlorohydrin. The reaction is expediently carried out in the presence of bases.

Aliphatic polycarboxylic acids can be used as the compound having at least two carboxyl groups in the molecule. Examples of such polycarboxylic acids are oxalic acid, succinic acid, glutaric acid, adipic acid, pimelic acid, suberic acid, azelaic acid or dimerized or trimerized linoleic acid.

However, it is also possible to use cycloaliphatic polycarboxylic acids, such as, for example, tetrahydrophthalic acid, 4-methyltetrahydrophthalic acid, hexahydrophthalic acid or 4-methylhexahydrophthalic acid.

It is furthermore possible to use aromatic polycarboxylic acids, such as, for example, phthalic acid, isophthalic acid or terephthalic acid.

II) Polyglycidyl or poly(β-methylglycidyl)ethers, obtainable by reacting a compound having at least two free alcoholic hydroxyl groups and/or phenolic hydroxyl groups with epichlorohydrin or β-methylepichlorohydrin under alkaline conditions or in the presence of acidic catalysts with subsequent alkali treatment.

The glycidyl ethers of this type are derived, for example, from acyclic alcohols, for example from ethylene glycol, diethylene glycol or higher poly(oxyethylene)glycols, propane-1,2-diol or poly(oxypropylene)glycols, propane-1,3-diol, butane-1,4-diol, poly(oxytetramethylene)glycols, pentane-1,5-diol, hexane-1,6-diol, hexane-2,4,6-triol, glycerol, 1,1,1-trimethylolpropane, pentaerythritol or sorbitol, and from polyepichlorohydrins.

Further glycidyl ethers of this type are derived from cycloaliphatic alcohols, such as 1,4-cyclohexanedimethanol, bis(4-hydroxycyclohexyl)methane or 2,2-bis(4-hydroxycyclohexyl)propane, or from alcohols which contain aromatic groups and/or further functional groups, such as N,N-bis(2-hydroxyethyl)aniline or p,p′-bis(2-hydroxyethylamino)diphenylmethane.

The glycidyl ethers can also be based on mononuclear phenols, such as, for example, resorcinol or hydroquinone, or on polynuclear phenols, such as, for example, bis(4-hydroxyphenyl)methane, 4,4′-dihydroxybiphenyl, bis(4-hydroxyphenyl) sulphone, 1,1,2,2-tetrakis(4-hydroxyphenyl)ethane, 2,2-bis(4-hydroxyphenyl)propane or 2,2-bis(3,5-dibromo-4-hydroxyphenyl)propane.

Further suitable hydroxy compounds for the preparation of glycidyl ethers are novolaks obtainable by condensation of aldehydes, such as formaldehyde, acetaldehyde, chloral or furfuraldehyde, with phenols or bisphenols which are unsubstituted or substituted by C₁-C₉-alkyl groups, such as, for example, phenol, 4-chlorophenol, 2-methylphenol or 4-tert-butylphenol.

III) Poly(N-glycidyl) compounds, obtainable by dehydrochlorination of the reaction products of epichlorohydrin with amines which contain at least two amine hydrogen atoms. These amines are, for example, aniline, n-butylamine, bis(4-aminophenyl)methane, m-xylylenediamine and bis(4-methylaminophenyl)methane.

The poly(N-glycidyl) compounds also include triglycidyl isocyanurate, N,N′-diglycidyl derivatives of cycloalkyleneureas, such as ethyleneurea or 1,3-propyleneurea, and diglycidyl derivatives of hydantoins, such as 5,5-dimethylhydantoin.

IV) Poly(S-glycidyl) compounds, for example di-S-glycidyl derivatives which are derived from dithiols, such as, for example, ethane-1,2-diol or bis(4-mercaptomethylphenyl)ether.

V) Cycloaliphatic epoxy resins, such as, for example, bis(2,3-epoxycyclopentyl)ether, 2,3-epoxycyclopentyl glycidyl ether, 1,2-bis(2,3-epoxycyclopentyloxy)ethane or 3,4-epoxycyclohexylmethyl 3′,4′-epoxycyclohexanecarboxylate.

It is also possible to use epoxy resins in which the 1,2-epoxide groups are bonded to different hetero atoms or functional groups; these compounds include, for example, N,N,O-triglycidyl derivative of 4-aminophenol, the glycidyl ether glycidyl ester of salicylic acid, N-glycidyl-N′-(2-glycidyloxypropyl)-5,5-dimethylhydantoin and 2-glycidyloxy-1,3-bis(5,5-dimethyl-1-glycidylhydantoin-3-yl)propane.

Compositions which form a solid layer after drying are preferably used for the coating. The formation of a solid layer can be controlled by the choice of the components of the overall composition or a preliminary reaction during the drying, which can be determined by a person skilled in the art by simple testing. Preferred examples for solid polyepoxides are solid polyglycidyl ethers or polyglycidyl esters, in particular solid diglycidyl ethers of a bisphenol or solid diglycidyl esters of a cycloaliphatic or aromatic dicarboxylic acid, or a solid cycloaliphatic epoxy resin. Furthermore, solid epoxide novolaks are particularly suitable. Mixtures of epoxy resins may also be used.

All known curing agents can be used as curing agents for the curable epoxy resins in the coating formulation if, together with the other components, said curing agents form a dry layer after removal of the solvent. The formation of a dry layer can be tested by a person skilled in the art as mentioned above in a simple manner. Curing agents for epoxy resins are preferably selected from the group consisting of the basic curing agents, nitrogen- and phosphorus-containing curing agents being particularly preferred, such as, for example, imidazoles, amides and polyamines. Furthermore, phenol resins, polycarboxylic acids and the anhydrides thereof, and cyanate esters, are also suitable.

Examples of curing agents in combination with epoxide compounds are polycarboxylic acids, polyamines, polyaminoamines, adducts of an amine and a polyepoxide compound which contain amino groups, aliphatic and aromatic polyols and catalytic curing agents.

For example, the following may be mentioned as suitable polycarboxylic acids: aliphatic polycarboxylic acids, such as maleic acid, oxalic acid, succinic acid, nonyl- or dodecylsuccinic acid, glutaric acid, adipic acid, pimelic acid, suberic acid, azelaic acid or dimerized or trimerized linoleic acid; cycloaliphatic polycarboxylic acids, such as, for example, tetrahydrophthalic acid, methylendomethylenetetrahydrophthalic acid, hexachloroendomethylenetetrahydrophthalic acid, 4-methyltetrahydrophthalic acid, hexahydrophthalic acid or 4-methylhexahydrophthalic acid, or aromatic polycarboxylic acids, such as, for example, phthalic acid, isophthalic acid, terephthalic acid, trimellitic acid, pyromellitic acid or benzophenone-3,3′,4,4′-tetracarboxylic acid, and the anhydrides of said polycarboxylic acids.

Aliphatic, cycloaliphatic, aromatic or heterocyclic amines may be used as polyamines for the curing, such as, for example, ethylenediamine, propane-1,2-diamine, propane-1,3-diamine, N,N-diethylethylenediamine, hexamethylenediamine, diethylenetriamine, triethylenetetramine, tetraethylenepentamine, N-(2-hydroxyethyl)-, N-(2-hydroxypropyl)- and N-(2-cyanoethyl)diethyltriamine, 2,2,4-trimethylhexane-1,6-diamine, 2,3,3-trimethylhexane-1,6-diamine, N,N-dimethyl- and N,N-diethylpropane-1,3-diamine, ethanolamine, m- and p-phenylenediamine, bis(4-aminophenyl)methane, aniline/formaldehyde resin, bis(4-aminophenyl) sulphone, m-xylylenediamine, bis(4-aminocyclohexyl)methane, 2,2-bis(4-aminocyclohexyl)propane, 2,2-bis(4-amino-3-methylcyclohexyl)propane, 3-aminomethyl-3,5,5-trimethylcyclohexylamine(isophoronediamine) and N-(2-aminoethyl)piperazine, and, as polyaminoamides, for example those obtained from aliphatic polyamines and dimerized or trimerized fatty acids.

Suitable polyaminoamides are, for example, the reaction products obtained by reaction of polycarboxylic acids, preferably of dimerized fatty acids, with polyamines in a molar excess, as described, for example, in Handbook of Epoxy Resins, 1967, pages 10-2 to 10-10, by H. Lee and K. Neville.

Adducts of an amine and a polyepoxide compound which contain amino groups are likewise curing agents for epoxy resins and can be used for the curing of the epoxy resin compositions according to the invention and are obtained, for example by reaction of epoxy resins with polyamines in an equivalent excess. Such adducts containing amino groups are described in more detail, for example, in U.S. Pat. Nos. 3,538,184; 4,330,659; 4,500,582 and 4,540,750.

For example, ethylene glycol, diethylene glycol and higher poly(oxyethylene)glycols, propane-1,2-diol or poly(oxypropylene)glycols, propane-1,3-diol, butane-1,4-diol, poly(oxytetramethylene)glycols, pentane-1,5-diol, hexane-1,6-diol, hexane-2,4,6-triol, glycerol, 1,1,1-trimethylolpropane, pentaerythritol, sorbitol, N,N-bis(2-hydroxyethyl)aniline or p,p′-bis(2-hydroxyethylamino)diphenylmethane are suitable as aliphatic polyols for the curing of the epoxy resin composition according to the invention.

For example, mononuclear phenols, such as resorcinol or hydroquinone or polynuclear phenols, such as bis(4-hydroxyphenyl)methane, 4,4′-dihydroxybiphenyl, bis(4-hydroxyphenyl) sulphone, 1,1,2,2-tetrakis(4-hydroxyphenyl)ethane, 2,2-bis(4-hydroxyphenyl)propane, 2,2-bis(3,5-dibromo-4-hydroxyphenyl)propane and novolaks obtainable by condensation of aldehydes, such as formaldehyde, acetaldehyde, chloral or furfuraldehyde, with phenols, such as phenol, or with phenols which are substituted in the nucleus by chlorine atoms or C₁-C₉-alkyl groups, such as, for example, 4-chlorophenol, 2 -methylphenol or 4-tert-butylphenol, or by condensation of bisphenols, for example those of the abovementioned type, can be used as aromatic polyols for the curing.

It is also possible to use catalytic curing agents for the curing of the epoxy resin compositions according to the invention, such as tertiary amines, for example 2,4,6-tris(dimethylaminomethyl)phenol and other Mannich bases, N-benzyldimethylamine and triethanolamine; alkali metal oxides of alcohols, for example the sodium alcoholate of 2,4-dihydroxy-3-hydroxymethylpentane; tin salts of alkanoic acids, for example tin octanoate; Friedel-Crafts catalysts, for example boron trifluoride and its complexes, for example boron trifluoride-amine complexes, and chelates which are obtained by reaction of boron trifluoride with, for example, 1,3-diketones, sulphonium salts, as disclosed, for example, in European Patent 0 379 464 or U.S. Pat. No. 5,013,814, in European Patent 0 580 552 or U.S. Pat. No. 5,374,697, or heterocyclic ammonium salts, for example quinolinium salts mixed with benzpinacol, as mentioned, for example, in EP-A-0 066 543.

Initiators which can be activated by irradiation and which, after the irradiation, act as thermal curing agents, in particular in combination with epoxide compounds, can also be used as curing agents. In this case, applied layers are exposed to light, preferably UV light, after drying and before lamination with a metal foil. Such initiators are preferably selected from the group consisting of the aryldiazonium salts, diaryliodonium salts, such as, for example, diphenyliodonium tetrafluoroborate and the like, triarylsulphonium salts, such as, for example, triphenylsulphonium hexafluoroantimonate and the like, arylacyidialkylsulphonium salts, 1,2-quinonediazide-4-carboxylic acid ester, 1,2-quinonediazide-4-sulphonic acid ester, 4-(2-ethylhexanoyl)resorcinol-1,2-naphthoquinonediazide-4-sulphonic acid ester and the like, and iron-arene complexes. The latter are compounds of the formula

[R¹(Fe^{II}R²)]⁺[X)]⁻

in which R¹ is a π-arene and R² is a π-arene or a π-arene anion. Preferably, R¹ is an η⁶-cumene, η⁶-naphthalene, η⁶-benzene or η⁶-pyrrole. R² is preferably an η⁵-cyclopentadiene. X is a nonnucleophilic anion. Particularly preferred examples of X include BF₄⁻, PF₆⁻, AsF₆⁻, SbF₆⁻, SbF₅OH⁻, sulphonates, such as methylsulphonate, p-tolylsulphate and the like, perfluoroalkyl sulphonates, such as, for example, trifluoromethylsulphonates, nonafluorobutyl sulphonates and the like, acetates, such as CH₃COO⁻ and the like, perfluoroacetates, such as CF₃COO⁻ and the like, halogens, such as F⁻, Cl⁻, Br⁻, I⁻ and the like, pseudohalogens, such as CN⁻, SCN⁻ and the like. Preferably, X is a sulphonate, a perfluorosulphonate or PF₆⁻. It is known to a person skilled in the art that, at their thermal decomposition point, free radical, anionic and cationic initiators can initiate thermal decomposition reactions in the absence of light. By a skilful choice of the decomposition reaction of the initiators, it is possible to adjust the curing temperature during the compression process or to express it during the drying process.

Thermal and photochemical curing agents can also be used with accelerators. Preferred accelerators are benzyldimethylamine, 2-phenylimidazole and 2-methylimidazole, which is added for increasing the Tg point (glass transition temperature) and/or more rapid curing. The higher the Tg point, the higher the temperature at which the polymer is transformed from a glassy into a virtually elastomeric state. On the basis of his knowledge of the Tg point, a person skilled in the art can adjust the Tg point so that dimensional changes, deformations and distortions of the intermediate layer are avoided.

Suitable solvents in the coating formulation are polar, in particular polar, aprotic solvents. The solvents can be used alone or as a mixture with other solvents. Possible solvents are: ethers, halogenated hydrocarbons, carboxylic esters, lactones, sulphones, ketones and substituted benzenes. Diethylene glycol ethyl ether acetate and dipropylene glycol methyl ether and mixtures thereof are particularly preferred.

Fillers are frequently added to the coating formulation. Examples of these are inorganic fillers, such as barium sulphate, barium titanate, silica, talc, calcium carbonate, calcium magnesium carbonate, ammonium phosphate, mica, magnesium hydroxide, aluminium hydroxides and the like, or organic fillers, such as silicone powder, nylon powder, microgels, fluoride powder and the like.

If necessary, additives are also added in the coating formulation. Examples of these are thixotropic agents, such as aerosil, orben, bentone, montmorillonite and the like.

Further additives which are preferably present in the coating formulation are antifoams and dyes, such as phthalocyanine blue, phthalocyanine green, crystal violet, titanium oxide and the like.

Various metal foils having different conductivities can be used for the coating, copper foils being particularly preferred. Other preferably used metal foils are those of aluminium, those of copper alloys and those of metals stable at high temperatures, such as nickel. Copper foils can be used in any desired thicknesses. Foils having a thickness greater than 10 μm are preferred. The lower limit is determined by mechanical stability of the foils. By using substrate foils, it is also possible to use thinner foils. Examples of such substrate foils are aluminium-copper foils.

Copper foils having a small thickness permit direct drilling/structuring by laser ablation. For this purpose, a layer which is applied to the metal foil, increases the absorption or reduces the reflection of the laser light can be applied. An example of this is a copper oxide layer, which permits direct use of CO₂ lasers. Time-consuming and expensive wet chemical etching processes (window etching process) for copper structuring or copper drilling are thus no longer necessary. The application of the copper foil to the intermediate layer means that a wet/plasma chemical roughening process is no longer necessary. Consequently, a very wide range of curable resins can be used for the method according to the invention.

Components produced by the method according to the invention and intended for electronic apparatuses have excellent mechanical, chemical and electrical properties and can also be economically produced.

A circuit board obtained by the method according to the invention is ready for further process steps, such as laser drilling, structuring of the copper, flash-etching for direct laser drilling with CO₂ lasers or window-etching. By means of the method according to the invention, the manufacturing tolerance can be considerably reduced, which in turn may lead to major cost saving in the subsequent processes. The circuit boards produced by the method according to the invention simplify the use of novel technologies, such as, for example, novel bond technologies, such as flipchip attachment. Furthermore, it is possible to save material, such as, for example, by reduction of the solder resist mask layer thickness.

The invention is explained in more detail below with reference to some figures. Therein:

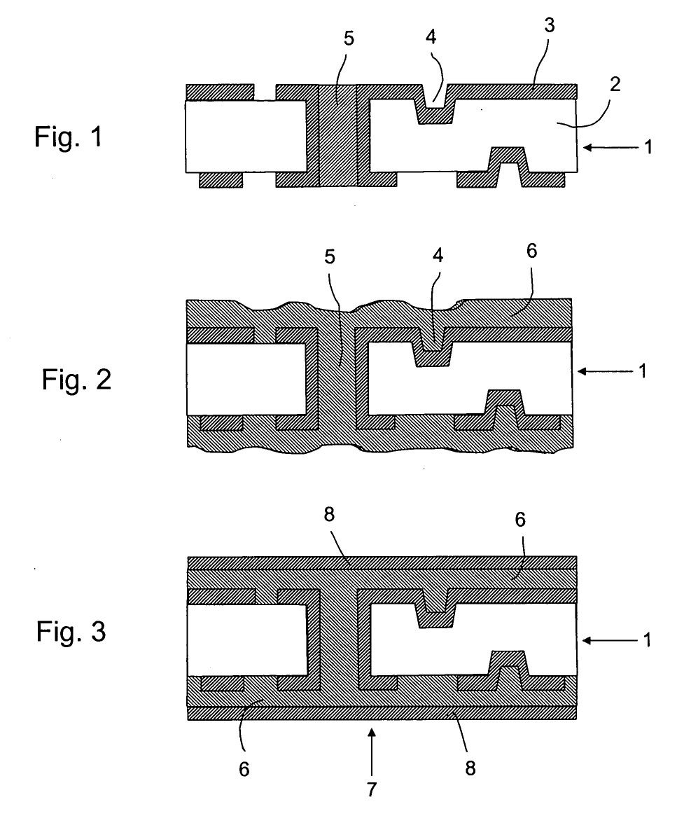

FIG. 1 shows the design of a structured inner layer;

FIG. 2 shows the structured inner layer after coating with a coating formulation and drying thereof and

FIG. 3 shows a completed circuit board produced by the method according to the invention.

FIG. 1 shows the design of a structured inner layer 1. Conductor tracks 3 are applied to an insulating layer 2. The insulating layer 2 is structured by vias 5 and microholes 4, these being produced by means of conventional drilling. The vias 5 and microholes 4 are likewise copper-plated and an integral component of the conductor tracks 3. The insulating layer 2 preferably consists of a curable resin, e.g. epoxy resin, reinforced with a glass fibre braid. This insulating layer 2 is known by the term PREPREG. Particularly preferably, the FR4 epoxy resin is reinforced with a glass fibre braid.

FIG. 2 shows the structured inner layer 1 after coating with the coating formulation 6 and drying thereof. The coating formulation 6 is applied to the structured inner layer by a method described above. The vias 4 and microholes 5 are filled thereby. After the coating of the structured inner layer 1 with the coating formulation 6, the latter is dried.

FIG. 3 shows the circuit board 7 produced by the method according to the invention. A metal foil 8 is applied to the intermediate layer 6 on the structured inner layer 1 and is pressed at elevated temperature, the curing of the curable resin taking place. As a result of the compression, the intermediate layer 6 becomes planar.

The examples which follow illustrate the invention in more detail.

### EXAMPLE 1

Composition of the Coating Formulation

| | |
|---|---|
| Promoted bisphenol A glycidyl ether | 40.00% |
| Epoxyphenol novolak | 10.00% |
| Silica-based thixotropic agent | 1.00% |
| Filler, CaMgCO₃ | 20.00% |
| Diethylene glycol ethyl ether acetate | 25.00% |
| Phenylimidazole | 0.5% |
| Cresol novolak | 3.0% |
| Additives | 0.2% |
| Total | 100.00% |

The coating formulation has a viscosity of 10 Pa·s.

A copper foil structured on one side and having a thickness of 12 μm is used.

The structured inner layer is coated with the above coating formulation by means of a furnace roller coater. The double coating is effected using an 800 roll (=800 μm grooving). The coating formulation is dried for 60 minutes at 80° C.

The press used is a multilayer press from Cedal having inductive heating (Adara model 57). In this press, the heating and pressure profile can be individually adjusted. The following parameters are used:

10 minutes at 80° C. at 4 kg/cm²,

25 minutes at 130° C. at 4 kg/cm²,

9 minutes at 175° C. at 10 kg/cm²,

20 minutes at 185° C. at 10 kg/cm².

The circuit board according to the invention has a copper adhesion of >14 N/cm (copper adhesion measurement according to IPC-TM-650 2.4.8), a planarity of <5 μm (planarity determination by means of IPC-TM-650 2.2.21) and a layer thickness distribution of <5 μm. The glass transition temperature of the cured resin in the coating formulation is 120° C. (determined by means of TMA).

### EXAMPLE 2

Composition of the Coating Formulation:

| | |
|---|---|
| Promoted bisphenol A glycidyl ether | 30.00% |
| Epoxyphenol novolak | 9.00% |
| Silica-based thixotropic agent | 0.70% |
| Filler, CaMgCO₃ | 15.00% |
| Diethylene glycol ethyl ether acetate | 25.00% |
| Copper(II) naphthenate (8% Cu) | 0.1% |
| Bisphenol A cyanate ester | 20.00% |
| Additives | 0.2% |
| Total | 100.00% |

The coating formulation has a viscosity of 10 Pa·s.

A copper foil structured on one side and having a thickness of 36 μm is used.

The structured inner layer is coated with the above coating formulation by means of coating with a doctor blade. The double coating is effected using a 100 μm doctor blade. The coating formulation is dried for 60 minutes at 80° C.

The compression is effected for 60 minutes at 150° C. at 10 kg/cm² in a press (manufacturer Carver, model C, 15×15 cm, heatable).

The circuit board according to the invention has a copper adhesion of >14 N/cm (copper adhesion measurement according to IPC-TM-650 2.4.8), a planarity of <5 μm (planarity determination by means of IPC-TM-650 2.2.21) and a layer thickness distribution of <5 μm. The glass transition temperature of the curable resin is 145° C. (determined by means of TMA).

1. A method for the production of components for electronic apparatuses from a sheet-like substrate material which has through-holes and indentations on at least one surface, an intermediate layer on at least one surface of the substrate material, and a metal foil adhering to said layer, comprising steps (a) coating of a sheet-like substrate material with a composition forming the intermediate layer, (b) application of the metal foil to the coating and (c) bonding of the parts under pressure and heat, characterized in that
(d) first a liquid, solvent-containing and heat-curable two-component system is formulated from at least one curing agent and at least one curable compound,
(e) the formulation is applied as a layer to at least one surface of the substrate material,
(f) the applied layer is heated, the solvent is removed and a solid and dry layer forms, and
(g) thereafter a metal foil is applied to the dried layer and the substrate material, the layer and the metal foil are firmly bonded to one another by means of elevated temperature and elevated pressure with curing of the layer.

2. A method according to claim 1, characterized in that the metal foil is applied to the intermediate layer immediately after drying.

3. A method according to claim 1, characterized in that the metal foil used is a copper foil.

4. A method according to claim 1, characterized in that the formulation of stage (d) for the method has a viscosity of less than 20 Pa·s, measured at 25° C. according to Brookfield.

5. A method according to claim 4, characterized in that the viscosity is from 5 to 15 Pa·s.

6. A method according to claim 1, characterized in that the drying in stage (f) is carried out at a temperature of not more than 100° C.

7. A method according to claim 1, characterized in that the drying is carried out for a duration of from 10 to 120 minutes.

8. A method according to claim 1, characterized in that the curable compound in the formulation of stage (d) is an epoxide compound having on average more than one epoxide group in the molecule.

9. A method according to claim 8, characterized in that the epoxide compound is an optionally prereacted diglycidyl ether of a bisphenol or is an epoxyphenol novolak.

10. A method according to claim 1, characterized in that the curing agent in the formulation of stage (d) is selected from the group consisting of the imidazoles, anhydrides, amides, amines, phenol resins and cyanate esters.

11. A method according to claim 1, characterized in that the formulation of stage (d) additionally contains curing accelerators, fillers, thixotropic agents and dyes.
